(19) United States
(12) Patent Application Publication
(10) Pub. No.: US 2026/0188820 A1
(43) Pub. Date: Jul. 2, 2026

(54) SMART SKID SUPPORT STRUCTURE SYSTEM FOR MODULAR BATTERY ENERGY STORAGE SYSTEMS (BESS)

(71) Applicants: Fluence Energy, LLC, Arlington, VA (US); Fluence Energy, LLC, Arlington, VA (US)

(72) Inventors: Suhas S, Bangalore (IN); Mark Austin Berger, Fulshear, TX (US); Lars Barkler, Larnum (DK); Steven McCaffrey, Torquay (AU); Vivek Annepu, VISAKHAPATNAM (IN); Niloy Sarkar, Jalpaiguri (IN)

(73) Assignee: Fluence Energy, LLC, Arlington, VA (US)

(21) Appl. No.: 19/437,132

(22) Filed: Dec. 30, 2025

Related U.S. Application Data
(60) Provisional application No. 63/739,705, filed on Dec. 30, 2024.

(51) Int. Cl. H01M 50/251; H01M 50/284; H05K 5/02; H05K 5/30; H05K 7/18; H05K 7/20

(52) U.S. Cl. CPC H01M 50/251; H01M 50/284; H05K 5/0217; H05K 5/0247; H05K 5/30; H05K 7/18; H05K 7/20318

(57) ABSTRACT

A smart skid support structure system includes a smart skid frame having at least one electrical connection access arranged within at least one of a pair of opposing ends, a top surface having a plurality of location features and a connection port arranged in the top surface, a bottom surface, a pair of opposing sides, a pair of opposing ends, a plurality of bays arranged within the smart skid frame, and a system cabling arranged within the smart skid frame. The smart skid support structure system further includes a plurality of electrical components arranged within the smart skid frame with at least one of the plurality of electrical components being arranged within at least one of the plurality of bays and at least one pod is configured for attachment to the smart skid support structure system.

### CROSS-REFERENCE TO RELATED APPLICATIONS

This application claims the benefit of U.S. Provisional Application Number 63/739,705, filed on Dec. 30, 2024, which is hereby incorporated by reference in its entirety.

### INTRODUCTION

The concepts described herein relate generally to battery energy storage systems (BESSs), and more specifically, to a “smart skid” support structure system for BESS nodes within modular BESSs.

Current BESSs generally include a plurality of BESS units or nodes arranged within a BESS node. Each BESS node includes a plurality of battery modules arranged in a battery rack or racks, and other BESS components, for example but not limited to chillers, heating, ventilation, and air conditioning (HVAC) systems, and/or power conversion systems (PCS), arranged within the BESS node having a floor, a rear side, left and right sides, doors, and a roof.

The configuration of the battery rack or racks and other BESS components arranged within each BESS node varies to meet the needs of different markets, and energy matching requirements across each BESS product line. To keep up with the changing market needs, implementation of changes within each BESS node, and into and across each BESS product line requires significant change-over time, effort, and cost in implementation.

For example, as demand for BESSs having greater storage capacity increases, an overall size and weight of each BESS node increase respectively. To implement this change, for example, a new battery module may be required, which may, in turn, require a new battery rack. As the plurality of battery modules, battery rack(s), and all other BESS system components for example but not limited to the chillers, HVAC systems, and power conversion systems, if so equipped, are arranged within a single BESS node, the entire BESS node including the other BESS system components require re-certification.

Further, each rack level BESS node includes node cabling configured to electrically connect the individual BESS node to, for example but not limited to, one another, a PCS, and/or a transformer via system cabling.

The node cabling from each individual BESS node is connected to the system cabling that runs underground to electrically connect the individual BESS nodes to, for example but not limited to, one another, the PCS, and/or the transformer.

Prior to installation of each individual BESS, an installation site needs to be prepared, which includes: excavation of the installation site to accommodate conduits, cables, and culverts; installation of the culverts, conduits, and hard cover; and installation of the cables electrically connecting the individual BESS nodes to one another, and all other BESS system components for example but not limited to the chillers, HVAC systems, PCS, and/or transformers.

To keep up with the changing market needs, implementation of changes within each individual BESS node, and into and across each BESS product line may require removal, updating and installation of updated individual BESS nodes, and/or installation of new individual BESS nodes.

Installation of updated individual BESS nodes and/or installation of new individual BESS nodes each require preparation and/or updating of the installation site, requiring significant installation time, effort and cost.

As such, it would be advantageous to provide a “smart skid” support structure system for modular BESS nodes including rack level BESS nodes or “pods” that incorporates the BESS system electrical and/or plumbing components, for example but not limited to, the chillers, HVAC systems, and PCS into the “smart skid” support structure system to facilitate and streamline the implementation of changes to both the BESS nodes and the other components, while streamlining the recertification process, and that facilitates installation of updated individual BESS nodes and/or new individual BESS nodes, while minimizing installation site preparation time, effort, and cost.

### SUMMARY

In view of the above discussion, it is useful to provide a “smart skid” support structure system for modular BESSs including rack level battery energy storage system (BESS) nodes or “pods” that incorporates BESS system electrical components, for example but not limited to, the chillers, HVAC systems, power conversion systems (PCS), and cabling into the “smart skid” support structure system to facilitate and streamline the implementation of changes to both the pods and the other BESS system components, while streamlining the recertification process, and that facilitates installation of updated individual pods and/or new individual pods, while minimizing installation site preparation time, effort, and cost.

The concepts disclosed herein relate to a “smart skid” support structure system for modular BESSs including rack level BESS node or “pods” that incorporates other components, for example but not limited to, the chillers, HVAC systems, power conversion systems, and cabling into the “smart skid” support structure system.

A modular BESS includes a plurality of individual BESS nodes electrically connected to one another and to at least one transformer. Each individual BESS node may include one or more BESS rack level nodes or pods attached to a “smart skid” support structure system.

An individual BESS node may include up to four pods attached to the “smart skid” support structure system.

Each “smart skid” support structure system may include a “smart skid” frame having a plurality of bays including but not limited to a controls bay, a first power conversion system (PCS) bay, a chiller bay, a second PCS bay, and an auxiliary/spare bay. Each of the plurality of bays may include BESS system electrical components, for example but not limited to, controls arranged within the controls bay, power conversion systems arranged within each of the first and second power conversion bays, chillers arranged within the chiller bay of the “smart skid” support structure system.

A “smart skid” support structure system may include a bottom surface, a top surface, a pair of opposing sides, and a pair of opposing ends. The top surface may include a plurality of location features, and a plurality of connection ports. The at least one of the pair of opposing sides include access to each of a controls bay, a first PCS bay, a chiller bay, a second PCS bay, and an auxiliary/spare bay. At least one electrical connection access is disposed within at least one of the two opposing ends.

The location features may be configured for locating pods adjacent to the “smart skid” support structure system.

The connection ports may be configured to provide access for electrical and coolant communication between pods and the “smart skid” support structure system.

A “smart skid” support structure system may include a plurality of direct current protection modules (DCPM), a plurality of power conversion systems (PCS), an electrical box, a chiller bay, and an auxiliary/spare bay. A cable bay may also be arranged within the “smart skid” support structure system.

An individual BESS unit including a plurality of pods may be arranged adjacent a top surface of the “smart skid” support structure system. Each pod may include a battery rack, and a plurality of battery modules. Each of the plurality of pods may be removably attached to the “smart skid” support structure system.

By providing a “smart skid” support structure system for modular BESSs including rack level battery energy storage system nodes or “pods” that incorporates BESS system electrical components, for example but not limited to, the chillers, HVAC systems, power conversion systems, and cabling into the “smart skid” support structure system, the “smart skid” support structure system facilitates and streamlines the implementation of changes to both the pods and the other components, while streamlining the recertification process, and that facilitates installation of updated individual pods and/or new individual pods, while minimizing installation site preparation time, effort, and cost.

The above features and advantages, and other features and attendant advantages of this disclosure, will be readily apparent from the following detailed description of illustrative examples and modes for carrying out the present disclosure when taken in connection with the accompanying drawings and the appended claims. Moreover, this disclosure expressly includes combinations and sub-combinations of the elements and features presented above and below.

### BRIEF DESCRIPTION OF THE DRAWINGS

The accompanying drawings, which are incorporated into and constitute a part of this specification, illustrate implementations of the disclosure which, taken together with the description, serve to explain the principles of the disclosure.

FIG. 1 is a front-view illustration of an example battery energy storage system (BESS).

FIG. 2 is a partially schematic perspective-view illustration of a representative battery energy storage system (smart stack system) in accordance with aspects of the present disclosure.

FIG. 3 is a partially schematic front-view illustration of the representative energy storage system of FIG. 2.

FIG. 4 schematically illustrates an embodiment of a power plant including a battery energy storage system (BESS) module including rack level BESS nodes or “pods” and a “smart skid” support structure system, in operative communication with and operably connected to an energy system, e.g., an electric grid, in accordance with aspects of the present disclosure.

FIG. 4A schematically illustrates an isometric view of a power plant including a plurality of BESS modules in accordance with aspects of the present disclosure.

FIG. 5 schematically illustrates an isometric view of a BESS module including rack level BESS nodes or pods configured for connection to a “smart skid” support structure system in accordance with aspects of the present disclosure.

FIG. 5A schematically illustrates an isometric view of a rack level BESS node or pod in accordance with aspects of the present disclosure.

FIG. 5B schematically illustrates an isometric view of a “smart skid” support structure system in accordance with aspects of the present disclosure.

FIG. 6 schematically illustrates a front view of a BESS module including a plurality of rack level BESS nodes or pods configured for connection to a “smart skid” support structure system in accordance with aspects of the present disclosure.

FIG. 7 schematically illustrates an isometric view of another representative “smart skid” support structure system in accordance with aspects of the present disclosure.

FIG. 8 schematically illustrates a front view of another representative “smart skid” support structure system in accordance with aspects of the present disclosure.

The appended drawings are not necessarily to scale and may present a somewhat simplified representation of various preferred features of the present disclosure as disclosed herein, including, for example, specific dimensions, orientations, locations, and shapes. Details adjacent to such features will be determined in part by the particular intended application and use environment.

### DETAILED DESCRIPTION

The components of the disclosed embodiments, as described and illustrated herein, may be arranged and designed in a variety of different configurations. Thus, the following detailed description is not intended to limit the scope of the disclosure, as claimed, but is merely representative of possible embodiments thereof. In addition, while numerous specific details are set forth in the following description in order to provide a thorough understanding of the embodiments disclosed herein, some embodiments may be practiced without some of these details. Moreover, for the purpose of clarity, certain technical material that is understood in the related art has not been described in detail in order to avoid unnecessarily obscuring the disclosure. Furthermore, the disclosure, as illustrated and described herein, may be practiced in the absence of an element that is not specifically disclosed herein.

The present disclosure is susceptible of embodiment in many different forms. Representative examples of the disclosure are shown in the drawings and described herein in detail as non-limiting examples of the disclosed principles. To that end, elements and limitations described herein, but not explicitly set forth in the claims, are not to be incorporated into the claims, singly or collectively, by implication, inference, or otherwise.

For purposes of the present description, unless specifically disclaimed, use of the singular includes the plural and vice versa, the terms “and” and “or” shall be both conjunctive and disjunctive, and the words “including,” “containing,” “comprising,” “having,” and the like shall mean “including without limitation.” Moreover, words of approximation such as “about,” “almost,” “substantially,” “generally,” “approximately,” etc., may be used herein in the sense of “at, near, or nearly at,” or “within 0-5% of,” or “within acceptable manufacturing tolerances,” or logical combinations thereof.

As used herein, the term “system” refers to mechanical and electrical hardware, software, firmware, electronic control componentry, processing logic, and/or processor device, individually or in combination, including without limitation: application specific integrated circuit (ASIC), an electronic circuit, a processor (shared, dedicated, or group) that executes one or more software or firmware programs, memory device(s) that electrically store software or firmware instructions, a combinatorial logic circuit, and/or other components that provide the described functionality.

As employed herein, terms such as “vertical”, “horizontal”, “left”, “right”, “upper”, “lower”, “top”, “bottom” and similar expressions are non-limiting terms that merely describe the various elements as illustrated in the Figures and are not intended to limit the scope of the disclosure.

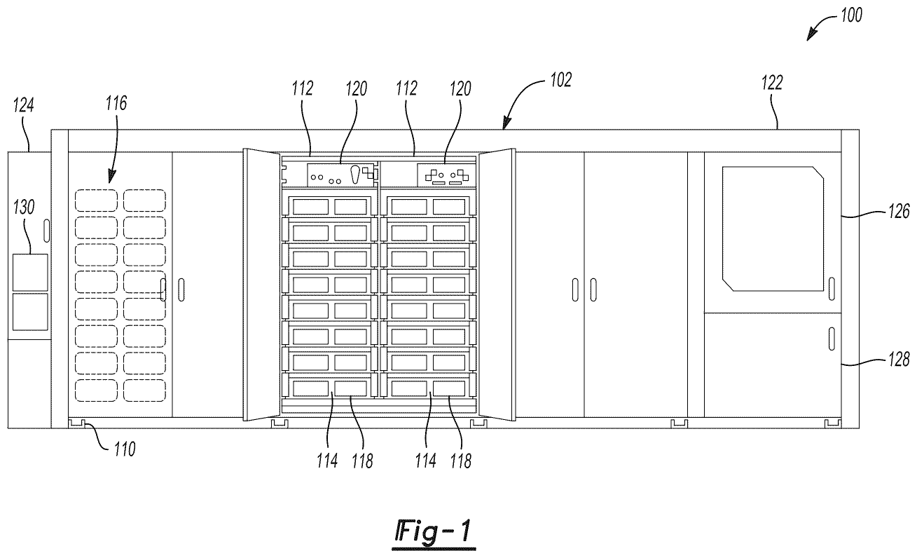

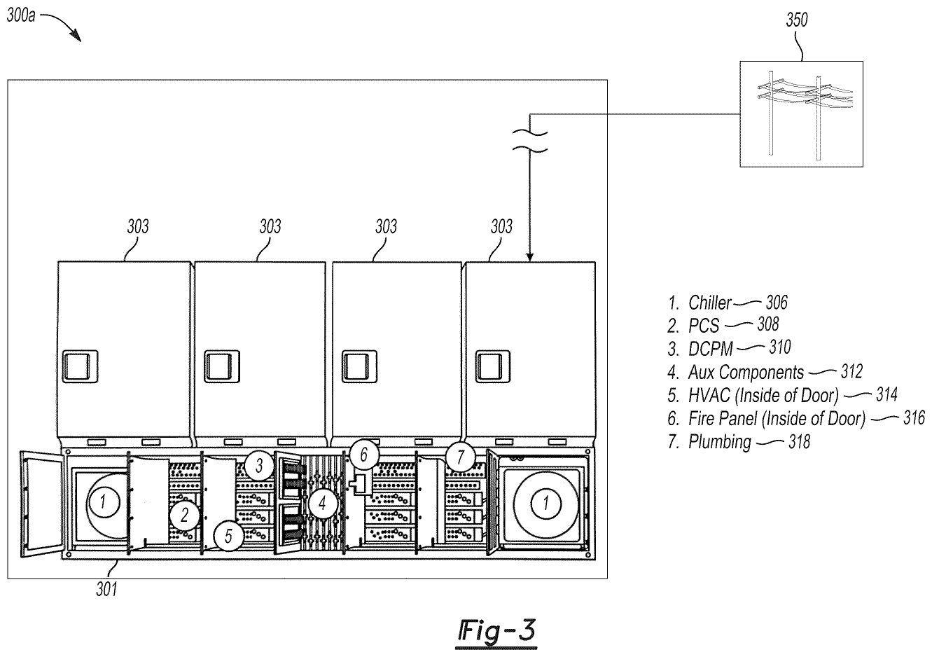

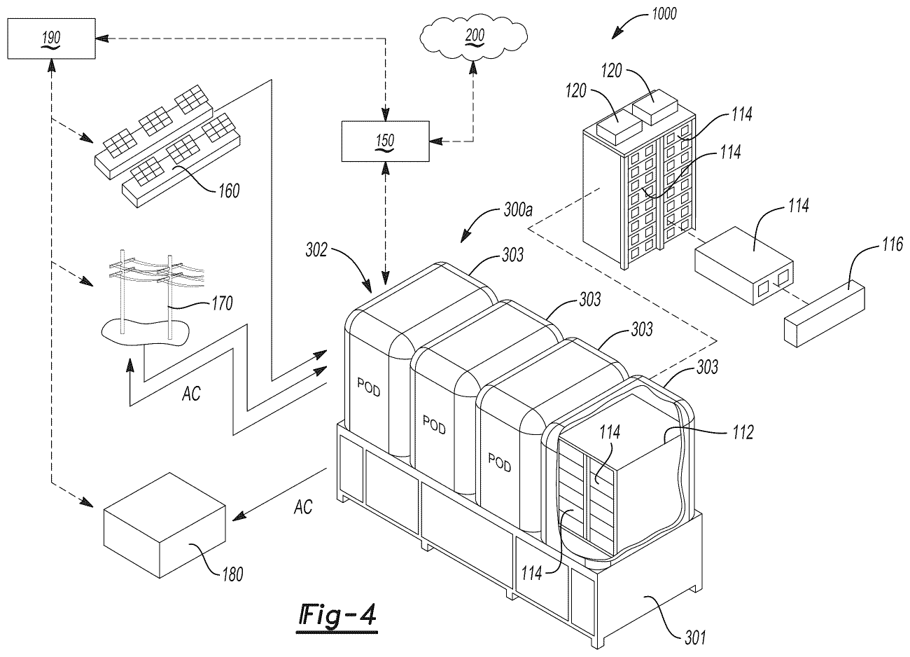

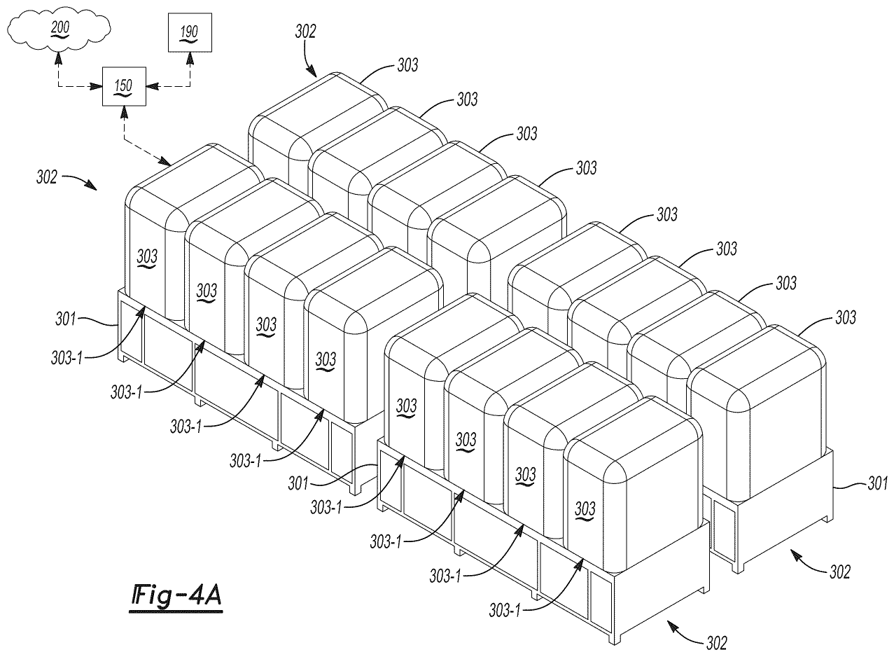

Referring to the drawings, wherein like reference numbers refer to the same or like components in the several Figures, FIG. 1 schematically illustrates a representative battery system, which is designated generally at 100 and portrayed therein for purposes of discussion as an interconnected network of high energy density, large discharge capacity modular battery energy storage system (BESS) nodes. The illustrated battery system 100—also referred to herein as “nodal BESS network” or “BESS” for short—is merely an exemplary application with which novel aspects of this disclosure may be practiced. In the same vein, incorporation of the present concepts into the nodal BESS network of FIGS. 3 and 4 for storing and dispensing energy in a utility power grid with two renewable energy subsystems should also be appreciated as non-limiting applications of disclosed features. As such, it will be understood that aspects and features of this disclosure may be utilized for a variety of different BESS form factors, integrated into assorted BESS network architectures, and incorporated into any logically relevant type of energy storage system. Moreover, only select components of the BESS node and BESS network are shown and described in detail below. Nevertheless, the BESS nodes and networks discussed herein may include numerous additional and alternative features, and other available peripheral hardware, for carrying out the various methods and functions of this disclosure.

The battery system 100 of FIG. 1 contains one or more modular BESS nodes 102, for example, to provide energy storage for load levelling of an electrical grid or energy storage for transient sources of electrical energy, such as solar cells or wind turbine generators. Each BESS node 102 may include a protective, weather-resistant BESS enclosure 110 within which are stored the energy storage devices and attendant componentry of the BESS 100. As shown, the BESS enclosure 110 houses a row of (six) battery racks 112 that each supports thereon a set of (eight) battery modules 114. Each battery module 114 contains a stack of (sixteen) rechargeable battery cells 116, such as lithium-ion, sodium-ion, or vanadium flow cells, and a bottom-layer battery module unit (BMU) 118 that functions as a supervisory component for monitoring and coordinating operation of the battery cells 116. Packaged on top of each rack 112 is a middle-layer battery cluster management (BCM) unit 120 that sits at the middle tier of the BESS's hierarchical Battery Management System (BMS) for receiving and processing data from the multiple BMUs 118 within its designated battery cluster.

Located at opposing ends of the BESS enclosure 110, adjacent the storage cabinets that stow the battery racks 112, are two self-contained hardware bays 122 and 124 for housing auxiliary components that support the efficient functioning of the BESS node 102. For instance, bay 122 of FIG. 1 may house a heating, ventilating, air conditioning (HVAC) system 126 that governs the internal operating temperatures inside the cabinets where the battery modules 114 are located. Hardware bay 122 may also house a chiller 128 for selectively chilling coolant that is circulated to the battery modules 114 in order to maintain the battery cells 116 within their specified operational temperature ranges. Located within bay 122, at the opposite end of the BESS enclosure 110, is one or more external units 130, which may include, for example but are not limited to, a bidirectional power transformer that boosts (“steps-up”) voltage output by the battery cells 116 to a level suitable for the grid or other components within the system, or decreases (“steps-down”) incoming voltage for recharging the battery cells 116, and/or a power conversion system that is configured to standardize power input and output between the plurality of BESS nodes 102 and the external power source 160 (FIG. 4). The power conversion system may include, for example but not limited to, one or multiple power converters (or inverters) configured to convert AC power to DC power, and/or DC power to AC power.

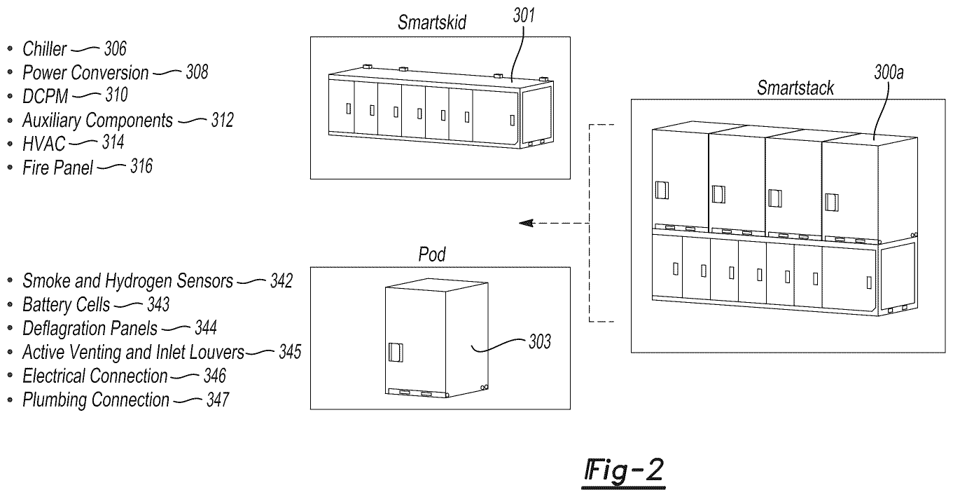

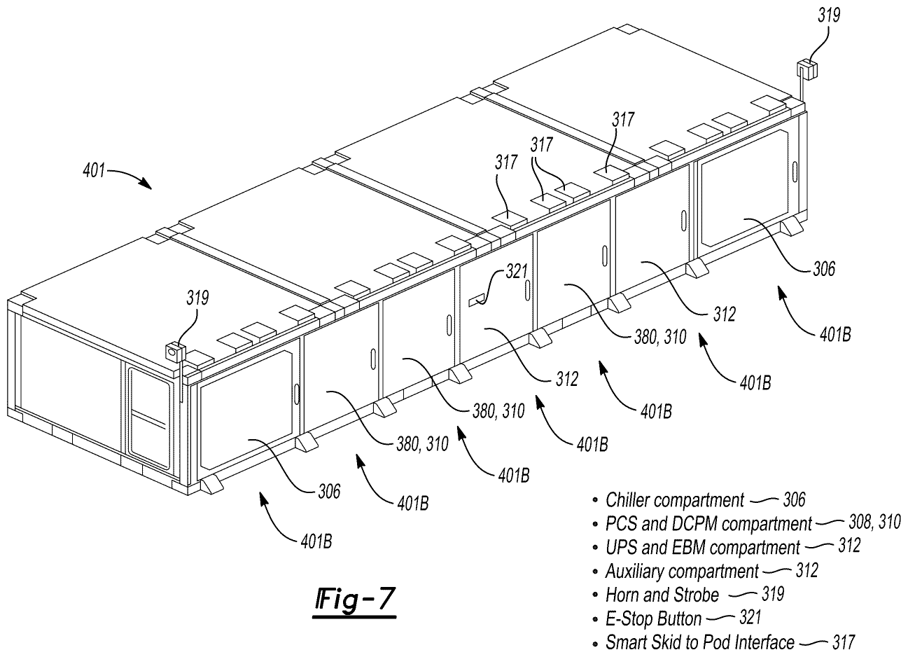

Turning now to FIG. 2, there is shown an example of a representative energy storage system or “smart stack” 300a with which aspects of the present disclosure may be practiced. The energy storage system 300a includes a “smart skid” support structure system 301 and a BESS node generally designated at 302 having multiple (e.g., four) rack level battery nodes or pods 303 seated on and secured to the “smart skid” 301. The “smart skid” 301 of FIG. 2 contains a chiller (cooler) 306, a power conversion system 308, a DC-DC power module (DCPM) 310, a set of auxiliary skid components 312, an HVAC system 314, and a fire panel 316. Each pod 303 may contain a network of smoke and hydrogen sensors 342, a set of interconnected and rechargeable battery cells 343, multiple deflagration panels 344, active venting and inlet louvers 345, a network of electrical connections 346, and a network of fluid plumbing connections 347. The auxiliary skid components may include but are not limited to an auxiliary transformer an aerosol canister, an uninterruptible power supply (UPS), and an extended battery module (EBM) systems (FIG. 7).

FIG. 3 provides a partially schematic, front-view illustration of the energy storage system or “smart stack” 300a shown operatively connected to an external power source 350, such as a utility power grid, renewable energy system, etc. The “smart skid” support structure system 301 of FIG. 3 generally includes two chillers (coolers) 306, the power conversion system 308, the DCPM 310, the auxiliary components 312, the HVAC system 314, the fire panel 316, and the plumbing 318. The energy storage system 300a may be coupled with the external power source 350. Although differing in appearance, it is envisioned that the energy storage system 300a of FIGS. 2 and 3 may include any of the features and options described above with reference to the battery system 100 of FIG. 1, and vice versa.

Turning now to FIG. 4 with continued reference to FIGS. 2 and 3, a power plant 1000 for a utility power grid includes a battery energy storage system (BESS) 300a in communication with a BESS controller 150, which is configured to monitor and control the various components included in the BESS 300a. The BESS 300a includes one or more rack level BESS nodes 303 or “pods,” and a “smart skid” support structure system 301, which may include other BESS system components, for example but not limited to a cooler 308, a power conversion system 308, a DC-DC power module (DCPM) 310, a set of auxiliary skid components 312, an HVAC system 314, and a fire panel 316.

As illustrated in FIG. 3, each pod 303 may contain a network of smoke and hydrogen sensors 342, a set of interconnected and rechargeable battery cells 343, multiple deflagration panels 344, active venting and inlet louvers 345, a network of electrical connections 346, and a network of fluid plumbing connections 347.

Each of the pods 303 includes a battery rack 112 having a plurality of battery modules 114. Each of the plurality of battery modules 114 includes a plurality of battery cells 116 arranged within each of the plurality of battery modules 114.

Each of the pods 303 are individually coupled mechanically, electrically, and/or fluidly to the “smart skid” support structure system 301, which includes other BESS system components 125 (FIGS. 2 and 3).

Referring back to FIG. 4, the pods 303, individually and collectively, are operable to store alternating current (AC) power delivered from an external power source 160 as direct current (DC) power, for example but not limited to when the demand for power from the external power source 160 is lower than the external power source 160 is operable to generate. The pods 303, individually and collectively, are further operable to provide DC power for an electrical application 170, which may include an electrical grid, for example but not limited to when the demand for power is higher than the external power source 160 is operable to generate. It should be appreciated that each of the pods 303 may be coupled to one another not only electrically, but also mechanically, and/or fluidly.

According to one aspect of the disclosure, to facilitate the conversion of AC power to DC power and DC power to AC power, the “smart skid” support structure system 301 may include a power conversion system (PCS) that is configured to standardize power input and output between the pod 303 and the external power source 160. The PCS may include, for example but not limited to, one or multiple power converters (or inverters) configured to convert AC power to DC power, and/or DC power to AC power.

According to one aspect of the disclosure, the BESS 100 is configured to provide power to an auxiliary power system 180, which may include but is not limited to battery and power converter thermal management, control systems, communications, etc.

A substation controller 190 communicates with the BESS plant controller 150 to operate and monitor the power plant 1000 including but not limited to receiving commands from a customer and converting the commands into BESS controls and site-specific commands.

The BESS controller 150 for the power plant 1000 is the interface to the customer and an external Supervisory Control and Data Acquisition (SCADA) system 200. The external SCADA system 200 is a computer-based system that monitors and controls industrial processes and equipment. The external SCADA system 200 uses a combination of hardware and software to collect data from devices and equipment, and then apply operational controls over long distances. The external SCADA system 200 may be used to monitor processes, maintain and improve efficiencies, improve quality and profitability, reduce waste, and identify problems and emergencies. Internally, it communicates with the BESS controller 150 and the substation controller 190 by which it operates and monitors the circuit breakers of the power plant 1000.

The external SCADA system 200 receives operating commands from the customer and converts them into plant controller-specific and site-specific commands (e.g. start/stop commands, operation modes, breaker operations . . . ). Additionally, it collects operating values of the power plant 1000 from the BESS controller 150 and the substation controller 190 and reports them to the customer and the external SCADA system 200.

Referring now to FIG. 4A with continued reference to FIGS. 2 and 3, the BESS 300a illustrated in FIG. 4, may include more than one BESS nodes 302 arranged adjacent to the “smart skid” support structure system 301 as illustrated in FIG. 4A. Each BESS node 302 includes one or more rack level BESS nodes 303 or “pods,” Each BESS node 302 including the one or more pods 303 is arranged in communication with the BESS controller 150, which is configured to monitor and control the various components included in each of the BESS nodes 302.

The BESS controller 150 communicates with a substation controller 190 to operate and monitor the power plant 1000, which includes but is not limited to receiving commands from a customer and converting the commands into BESS controls and site-specific commands.

The BESS controller 150 for the power plant 1000 is the interface to the customer and the SCADA system 200.

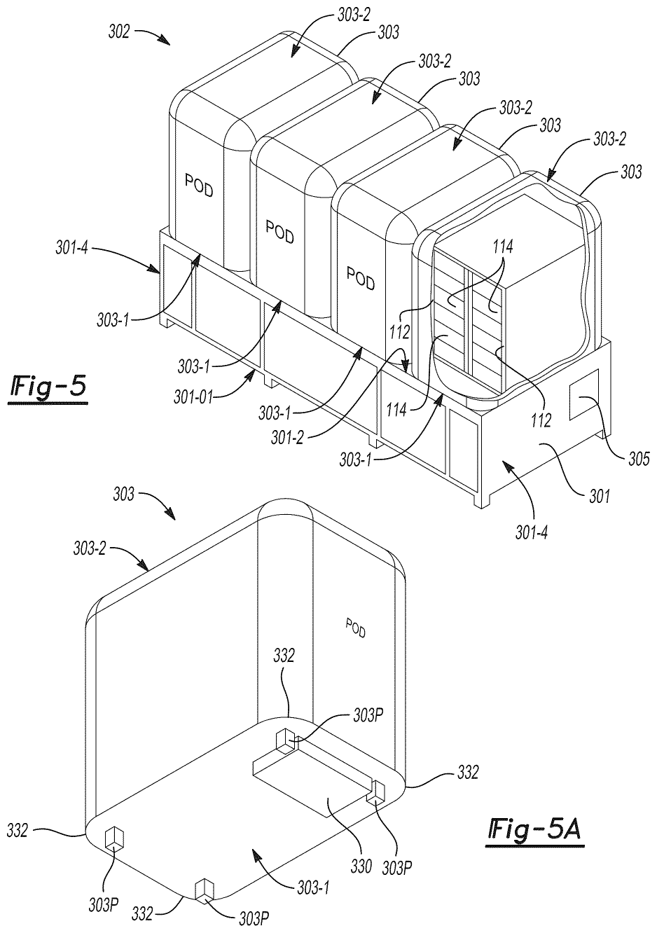

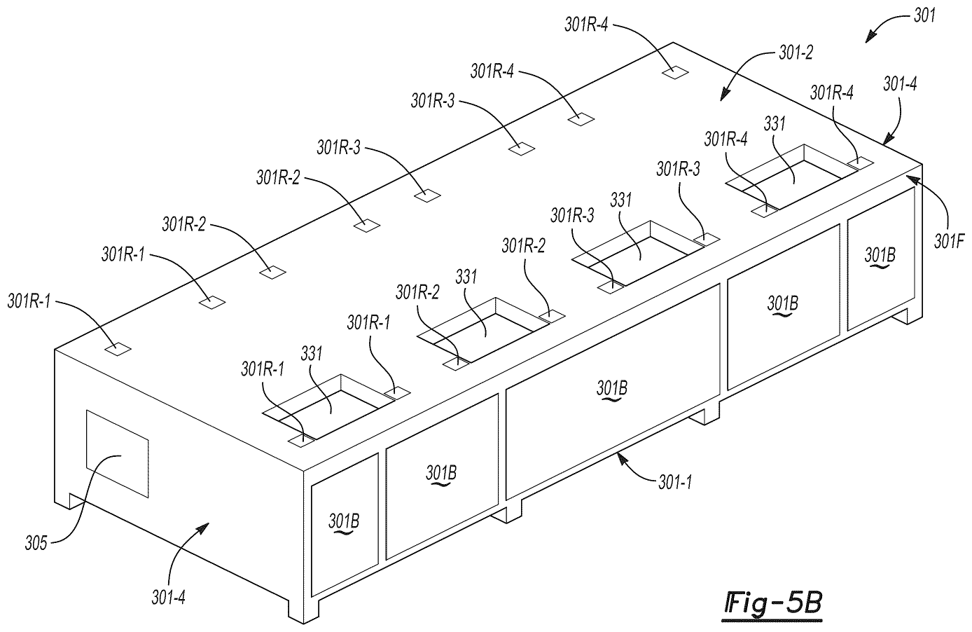

As schematically illustrated in FIG. 5, each of the BESS node 302 includes one or more pods 303 configured to be connected, mechanically and/or electrically, to the “smart skid” support structure system 301 at a smart skid to pod interface 317 (FIG. 7). Each rack level BESS node or pod 303 includes a bottom surface 303-1, and a top surface 303-2. At least one battery rack 112 is arranged within each pod 303.

As schematically illustrated in FIG. 5A, the bottom surface 303-1 of each pod 303 includes a plurality of locating protrusions 303P and a connection interface, schematically illustrated at 330, which is configured for engagement with and electrical connection to the “smart skid” support structure system 301 via connection port 331 arranged in a top surface 301-2 of the “smart skid” support structure system 301 (FIG. 5B).

The at least one battery rack 112 is configured to hold a plurality of battery modules 114, as illustrated in FIG. 3.

The plurality of locating protrusions 303P and the connection interface 330 each are arranged adjacent to the bottom surface 303-1 of the pod 303.

According to one aspect of the disclosure, the plurality of locating protrusions 303P includes four locating protrusions 303P for locating the pod 303 with respect to the “smart skid” support structure system 301 to facilitate connection, mechanically, electrically, and/or fluidly, of the pod 303 to the “smart skid” support structure system 301. Each of the four locating protrusions 303P are arranged at a respective corner 332 of the bottom surface 303-1 of the pod 303.

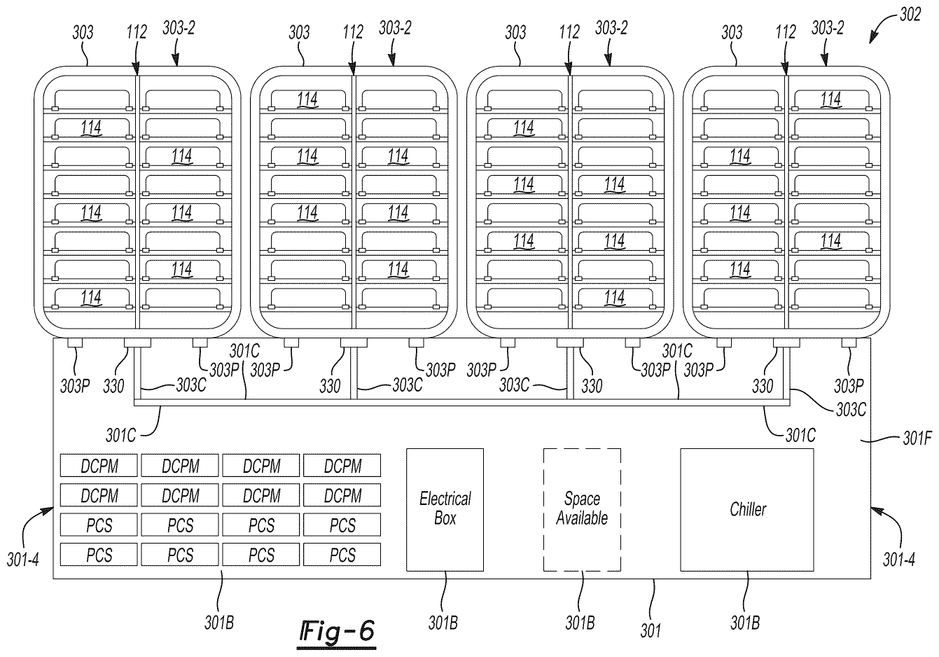

The connection interface 330 is arranged adjacent the bottom surface 303-1 of the pod 303. The connection interface 303-1 is configured to facilitate connection, mechanically, electrically, and/or fluidly of the pod 303 to the “smart skid” support structure system 301, via, for example but not limited to, node cabling and/or plumbing, schematically illustrated at 303C (FIG. 6) arranged within and extending from the bottom surface 303-1 of each pod 303 to, for example but not limited to, skid cabling and/or plumbing, schematically illustrated at 301C (FIG. 6) arranged within the and extending from the top surface 301-2 of the “smart skid” support structure system 301.

The node cabling and/or plumbing 303C and skid cabling and/or plumbing 301C may include, for example but not limited to, power cabling, controls cabling, auxiliary power cabling, cooling conduits, and the like.

The top surface 301-2 of the “smart skid” support structure system 301 is arranged externally adjacent to the bottom surface 303-1 of the pod 303.

As schematically illustrated in FIG. 5B, the top surface 301-2 of the “smart skid” support structure system 301 includes a plurality of locating receptacles 301R and a connection port 331. The bottom surface 303-1 of each pod 303 including the plurality of locating protrusions 303P and the connection interface, schematically illustrated at 330 is configured for engagement with and/or electrical connection to the “smart skid” support structure system 301 via the plurality of locating receptacles 301R and the connection port 331 arranged in the top surface 301-1 of the “smart skid” support structure system 301.

The plurality of locating receptacles 301R and the connection port 331 each are arranged adjacent to the top surface 301-2 of the “smart skid” support structure system 301.

According to one aspect of the disclosure, each plurality of locating receptacles 301R arranged in the “smart skid” support structure system 301 includes four pluralities of locating receptacles 301R-1, 301R-2, 301R-3, and 301-4, for respectively engaging four locating protrusions 303P arranged on respective bottom surfaces 303-1 of one or more pods 303 with to facilitate connection, mechanically, electrically, and/or fluidly, of the pod 303 to the “smart skid” support structure system 301.

The connection port 331 is arranged adjacent the top surface 313-2 of the “smart skid” support structure system 301. The connection port 331 is configured to facilitate connection, mechanically, electrically, and/or fluidly of the pod 303 to the “smart skid” support structure system 301, via, for example but not limited to, node cabling and/or plumbing, schematically illustrated at 303C (FIG. 6) arranged within and extending from the bottom surface 303-1 of each pod 303 to, for example but not limited to, skid cabling and/or plumbing, schematically illustrated at 301C (FIG. 6) arranged within the and extending from the top surface 301-2 of the “smart skid” support structure system 301.

Each “smart skid” support structure system 301 includes a “smart skid” frame 301F having plurality of bays 301B including for example but not limited to a controls bay, a power conversion system (PCS) bay, a chiller bay, a second PCS bay, and auxiliary/spare bays. Each of the plurality of bays may include components, for example but not limited to, controls arranged within the controls bay, power conversion systems arranged within each of the first and second power conversion bays, chillers arranged within the chiller bay of the “smart skid” support structure system 301.

As schematically illustrated in FIG. 6, a BESS node 302 includes one or more rack level BESS nodes or pods 303 configured to be mechanically, electrically, and/or fluidly connected to a “smart skid” support structure system 301 that is arranged externally adjacent to the rack level BESS nodes or pods 303.

According to the illustrated example, the BESS node 302 includes four BESS nodes or pods 303 configured for attachment to and/or removal from the “smart skid” support structure system 301.

Each pod 303 includes a bottom surface 303-1 and a top surface 303-2. At least one battery rack 112 is arranged within each pod 303.

The “smart skid” support structure system 301 may include, for example but not limited to, skid cabling 301C for electrical connection to node cabling 303C arranged within each pod 303, and a plurality of bays 301B, each of which includes, for example but not limited to, a plurality of direct current protection modules (DCPM), a plurality of power conversion systems (PCS), an electrical box, a chiller bay, a cable bay, and/or an auxiliary/spare bay.

It should be appreciated that the node cabling 303C and skid cabling 301C may include, for example but not limited to, power cabling, controls cabling, auxiliary power cabling, cooling conduits, and the like.

It should further be appreciated that each BESS node 302 may include more or less than four pods as required to accommodate different individual system specifications, and/or as needed to achieve and/or maintain system performance.

In the illustrated example configuration, the BESS node 302 includes four pods 303 configured for attachment to and/or removal from the “smart skid” support structure system 301.

Each of the four pods 303 includes a bottom surface 303-1, a top surface 303-2, and at least one battery rack 112 arranged within the pod 303.

The bottom surface 303-1 of each pod 303 includes a plurality of locating protrusions 303P and a connection interface 330. The at least one battery rack 112 is configured to hold a plurality of battery modules 114.

The plurality of locating protrusions 303P and the connection interface 330 are arranged adjacent to the bottom surface 303-1 of the pod 303.

The connection interface 330 is arranged adjacent to the bottom surface 303-1 of the pod 303. The connection interface 330 is configured to facilitate connection, mechanically, electrically, and/or fluidly of the pod 303 to the “smart skid” support structure system 301, via, for example but not limited to, node cabling and/or plumbing 303C within the pod 303 to, for example but not limited to, system cabling and/or plumbing 301C within the “smart skid” support structure system 301.

According to one aspect of the disclosure, a modular battery energy storage system (BESS) including one or multiple battery energy storage system (BESS) 300a, with each BESS 300a being arranged respectively adjacent to a “smart skid” support structure system 301 is also disclosed.

While the skid cabling and/or plumbing 301C is illustrated within the “smart skid” support structure system 301, it should be appreciated that the skid cabling and/or plumbing 301C may extend outward from the “smart skid” support structure system 301 through electrical connection accesses 305 arranged in at least one of a pair of opposing ends 301-4 of the “smart skid” support structure system 301 to provide for example but not limited to electrical, fluid, and/or communication connection between two or more BESS nodes 302.

While the plurality of bays 301B is illustrated in FIG. 6 as including a controls bay, a power conversion system (PCS) bay, a chiller bay, a second PCS bay, and an auxiliary/spare bay adjacent to one another, it should be appreciated that the plurality of bays may include bays other than the control bay, PCS bays, chiller bay, and auxiliary/spare bay, and the plurality of bays may have alternate configurations.

While the individual BESS node 302 is illustrated as having four pods 303, it should be appreciated that each individual BESS node may include one, two, three, four, or more pods 303 based on individual system requirements.

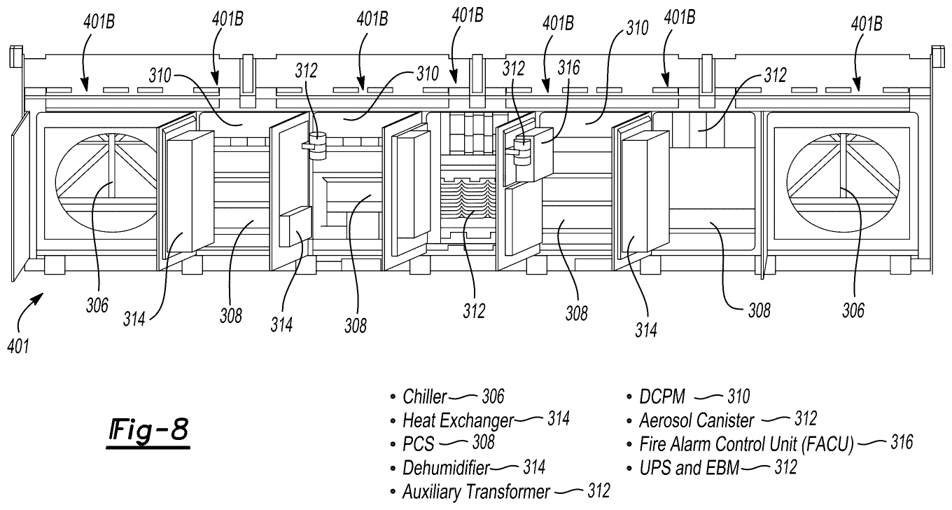

Referring now to FIGS. 7 and 8, another representative “smart skid” support structure system 401 includes a plurality of bays 401B, a horn and/or strobe 319, and an emergency stop (E-Stop) button 321 (FIG. 7), and a plurality of other BESS system components (FIG. 8) arranged within each of the plurality of bays 401B (FIG. 7).

As schematically illustrated in FIG. 7, the plurality of bays 401B includes, for example but not limited to, a chiller compartment or bay 306, PCS compartment or bay 308, DCPM compartment or bay 310, and auxiliary compartments or bays, e.g., an uninterruptible power supply (UPS) compartment or bay, and/or an extended battery module (EMB) compartment or bay. An emergency stop (E-Stop) button may be arranged adjacent to one of the plurality of bays, and a horn and/or strobe.

As schematically illustrated in FIG. 8, the plurality of other BESS system components includes, for example but not limited to, a chiller 306, a HVAC system (heat exchanger) 314, a PCS 308, an DCPM 310, a fire panel (fire alarm control unit (FACU)) 316, and auxiliary components 312, including for example, an auxiliary transformer, an aerosol canister, a UPS, and/or an EBM.

By providing a “smart skid” support structure system for modular BESSs including rack level battery energy storage system nodes or “pods” that incorporates BESS system electrical components, for example but not limited to, the chillers, HVAC systems, power conversion systems, and cabling into the “smart skid” support structure system, the “smart skid” support structure system facilitates and streamlines the implementation of changes to both the pods and the other components, while streamlining the recertification process, and that facilitates installation of updated individual pods and/or new individual pods, while minimizing installation site preparation time, effort, and cost.

These and other attendant benefits of the present disclosure will be appreciated by those skilled in the art in view of the foregoing disclosure.

The detailed description and the drawings or figures are supportive and descriptive of the present teachings, but the scope of the present teachings is defined solely by the claims. While some of the best modes and other examples for carrying out the present teachings have been described in detail, various alternative designs and aspects of the disclosure exist for practicing the present teachings defined in the appended claims.

What is claimed is:

1. A smart skid support structure system for a modular battery energy storage system (BESS), the smart skid support structure system comprising:
a smart skid frame including a plurality of electrical components arranged within the smart skid frame.

2. The smart skid support structure system as recited in claim 1, further including:
a plurality of bays disposed within the smart skid frame, each of the plurality of electrical components arranged within a respective one of the plurality of bays.

3. The smart skid support structure system as recited in claim 2, wherein the plurality of electrical components includes at least one of a control system, a power conversion system, and/or a chiller.

4. The smart skid support structure system as recited in claim 2, wherein the plurality of electrical components includes a control system, a power conversion system, and a chiller.

5. The smart skid support structure system as recited in claim 2, further including system cabling disposed within the smart skid frame.

6. The smart skid support structure system as recited in claim 2, further including a bottom surface, a top surface, a pair of opposing sides, and a pair of opposing ends.

7. The smart skid support structure system as recited in claim 6, further including at least one electrical connection system access disposed in at least one of the pair of opposing sides.

8. The smart skid support structure system as recited in claim 6, wherein the top surface includes a plurality of location features.

9. The smart skid support structure system as recited in claim 6, wherein the top surface includes a plurality of connection ports.

10. A modular battery energy storage system (BESS) comprising:
a smart skid support structure system including a smart skid frame; and
at least one pod configured for attachment to the smart skid support structure system;
wherein the smart skid support structure system includes a plurality of electrical components arranged within the smart skid frame; and
wherein the at least one pod includes at least one battery rack and a plurality of battery modules.

11. The modular BESS as recited in claim 10, wherein the smart skid support structure system includes:
a plurality of bays disposed within the smart skid frame, each of the plurality of electrical components arranged within a respective one of the plurality of bays.

12. The modular BESS as recited in claim 11, wherein the plurality of electrical components includes at least one of a control system, a power conversion system, and a chiller.

13. The modular BESS as recited in claim 12, wherein the plurality of electrical components includes at least a control system, a power conversion system, and a chiller.

14. The modular BESS as recited in claim 10, wherein the smart skid support structure system includes system cabling disposed within the smart skid frame.

15. The modular BESS as recited in claim 10, wherein the smart skid support structure system includes a bottom surface, a top surface, a pair of opposing sides, and a pair of opposing ends.

16. The modular BESS as recited in claim 15, wherein the smart skid support structure system includes at least one electrical connection system access disposed in at least one of the pair of opposing end portions.

17. The modular BESS as recited in claim 15, wherein the top surface includes a plurality of location features.

18. The modular BESS as recited in claim 17, wherein the plurality of location features includes a plurality of location receptacles.

19. The modular BESS as recited in claim 15, wherein the top surface includes a plurality of connection ports.

20. A modular battery energy storage system (BESS) including:
a smart skid support structure system including:
a smart skid frame having at least one electrical connection access arranged within at least one of a pair of opposing ends;
a bottom surface;
a top surface having a plurality of location features and a connection port arranged in the top surface;
a pair of opposing sides;
a pair of opposing ends;
a plurality of bays arranged within the smart skid frame; and
a system cabling arranged within the smart skid frame; and
at least one pod configured for attachment to the smart skid support structure system; and
wherein the smart skid support structure system includes a plurality of electrical components arranged within the smart skid frame, wherein at least one of the plurality of electrical components is arranged within at least one of the plurality of bays.
